(19) United States
(12) Patent Application Publication
(10) Pub. No.: US 2009/0128208 A1
(43) Pub. Date: May 21, 2009

(54) APPARATUS AND METHOD FOR DETECTING DUTY RATIO OF SIGNALS IN SEMICONDUCTOR DEVICE CIRCUIT

(76) Inventors: Taek-Sang Song, Gyeonggi-do (KR); Kyung-Hoon Kim, Gyeonggi-do (KR); Dae-Han Kwon, Gyeonggi-do (KR); Dae-Kun Yoon, Gyeonggi-do (KR)

Correspondence Address: MANNAVA & KANG, P.C., 11240 WAPLES MILL ROAD, Suite 300, FAIRFAX, VA, 22030, US

(21) Appl. No.: 12/263,690

(22) Filed: Nov. 3, 2008

(30) Foreign Application Priority Data
Nov. 2, 2007 (KR) 2007-0111495

(51) Int. Cl. H03K 3/017

(52) U.S. Cl. 327/175

(57) ABSTRACT

Apparatus for detecting duty ratio of signals in semiconductor device circuit includes a circuit for detecting a duty ratio of signals in a semiconductor device includes a comparing unit which compares a duty cycle of first and second input clock signals input differentially and generates a first output signal and a second output signal, a latching unit which stores the first and second output signals and generates a detected signal corresponding to the first and second output signals, and an adjusting unit which receives the first and the second output signals, and transmits the first and the second output signals to the latching unit based on a voltage level difference of the first and second output signals.

### CROSS-REFERENCE TO RELATED APPLICATIONS

This application claims priority of Korean patent application number 10-2007-0111495, filed on Nov. 2, 2007, which is incorporated by reference in its entirety.

### BACKGROUND OF THE INVENTION

The subject matter relates to a technology for designing a semiconductor device, and more particularly, to an apparatus and method for detecting a duty ratio of an input clock signal in a semiconductor device.

Generally, semiconductor memory devices such as double data rate synchronous dynamic random access memory (DDR SDRAM) have been developed for mass storage, high-speed data processing, and low power consumption. For the high-speed data processing, semiconductor memory devices are designed to operate in response to an external clock signal having a high frequency. For recent devices, the frequency of the external clock signal has advanced to gigahertz. The clock signal must be precise to operate in response to a supplied high frequency clock signal.

For example, if the external clock signal contains jitter or a duty ratio of the external clock signal is not 50 to 50, operating timing of a semiconductor memory devices using the external clock signal may not operate at the correct timing and thus the semiconductor memory device fails to operate stably.

In order to solve the above problem, the semiconductor memory device includes a duty cycle correction unit (DCC) for correcting an unbalanced duty ratio to 50 to 50.

FIG. 1 is a circuit diagram describing a conventional duty cycle correction circuit (DCC). Referring to FIG. 1, the DCC includes a comparing unit 110, a latching unit 130, and a compensating unit 150. The comparing unit 110 compares a first input clock signal IN with a second input clock signal INb, which are input differentially, and outputs first and second output signals OUT and OUTb. The comparing unit 110 includes a sensing and amplifying unit 112 for sensing and amplifying the first and second input clock signals IN and INb and an enable unit 114 for allowing the sensing and amplifying unit 112 to be operated in response to an enable signal EN.

The latching unit 130 stores the first and second output signals OUT and OUTb and outputs a detected-signal DET_OUT. The detected-signal DET_OUT is set to logic ‘high’ in response to the first output signal OUT being at logic ‘low’. The detected-signal DET_OUT is reset to logic ‘low’ in response to the second output signal OUTb being at logic ‘low’. The compensating unit 150 compensates the duty ratio of the first and second input clock signals IN and INb. The compensating unit 150 controls a pulse width of the first and second input clock signals IN and INb in response to the detected-signal DET_OUT.

Namely, what the second output signal OUTb being logic ‘low’ indicates is that a logic ‘high’ range of the first input clock signal IN is longer than a logic ‘high’ range of the second input clock signal INb. Accordingly, the compensating unit 150 shortens the logic ‘high’ range of the first input clock signal IN and lengthens the logic ‘high’ range of the second input clock signal INb in response to the detected-signal DET_OUT being at logic ‘low’.

FIG. 2 is a timing diagram describing a voltage level difference of the first and second output signals OUT and OUTb in response to the first and second input clock signals IN and INb of FIG. 1.

In FIG. 2 shows a situation in which a logic ‘high’ range of the first input clock signal IN is longer than a logic ‘low’ range of the signal IN. Conversely, a logic ‘high’ range of the second input clock signal INb is shorter than a logic ‘low’ range of the signal IN, as the second input clock signal INb has a phase inversed to the phase of the first input clock signal IN.

Referring to FIGS. 1 and 2, operation of the comparing unit 110 will be described simply hereinafter. First of all, a first NMOS transistor NM1 repeatedly performs turn-on and turn-off operations in response to the first input clock signal IN while an enable signal EN is activated to logic ‘high’. At this time, a first capacitor C1 is discharged. A second NMOS transistor NM2 repeatedly performs turn-on and turn-off operations in response to the second input clock signal INb. At this time, a second capacitor C2 is discharged. The discharge amount of the first capacitor C1 depends on an operating region of the first NMOS transistor NM1. The discharge amount of a first capacitor C2 depends on an operating region of the first NMOS transistor NM2. The operating region is one of a saturation region, a cut-off region, and a linear region.

In other words, the first NMOS transistor NM1 is turned on during the logic ‘high’ range of the first input clock signal IN, during which electric charge stored in the first capacitor C1 is discharged. The second NMOS transistor NM2 is turned on during the logic ‘high’ range of the second input clock signal INb, during which electric charge stored in the second capacitor C2 is discharged. Since the logic ‘high’ range of the first input clock signal IN is longer than the logic ‘high’ range of the second input clock signal INb, a turn-on range of the first NMOS transistor NM1 is longer than a turn-on a range of the second NMOS transistor NM2 and the discharge amount of the first capacitor C1 is larger than that of the second capacitor C2. Discharge of the first capacitor C1 is reflected as a decrease in voltage level of the second output signal OUTb. The discharging of the second capacitor C2 is reflected as a decrease in voltage level of the first output signal OUT. Thus, in this example, the voltage level of the second output signal OUTb decreases more rapidly than that of the first output signal OUT.

Equation 1, below, calculates voltage level difference ΔV_{OUTb} of the second output signal OUTb during the logic ‘high’ range Tₒₙ_{_{—}}IN of the first input clock signal IN.

Equation 2, below, calculates voltage level difference ΔV_{OUT} of the first output signal OUT during the logic ‘high’ range Tₒₙ_{_{—}}INb of the second input clock signal INb.

$$\begin{matrix}Δ {V}_{OUTb} = \frac{{I}_{on}}{{C}_{1}} {T}_{on} \_IN & [ Eq . 1 ] \\ Δ {V}_{OUT} = \frac{{I}_{on}}{{C}_{2}} {T}_{on} \_INb & [ Eq . 2 ]\end{matrix}$$

In Equation 1, C₁ denotes an electrostatic capacity of the first capacitor C1. Iₒₙ is a current through the third NNMOS transistor NM3 in the enable unit 114.

On the other hand, as the first and the second NMOS transistor NM1 and NM2 repeatedly perform operation of turn-on/turn-off, a difference of voltage levels of the first output signal OUT and the second output signal OUTb is getting broader. At this time, decreasing voltage level slope of the first output signal OUT is the same as the second output signal OUTb's.

But the voltage level of the second output signal OUTb decrease much rapidly than that of the first output signal OUT. Because the logic ‘high’ range of the first input clock signal IN is longer than the second input clock signal INb's, the discharge amount of the first capacitor C1 is greater than that of the second capacitor C2.

The sensing and amplifying unit 112 senses a voltage level difference between the first and second output signals OUT and OUTb and amplifies the first and second output signals OUT and OUTb. The latching unit 130 stores the first and second output signals OUT and OUTb amplified by the sensing and amplifying unit 112. The latching unit 130 outputs the detected-signal DET_OUT generated based on the first and second output signals OUT and OUTb. The latching unit 130 outputs the detected-signal DET_OUT that is reset to logic ‘low’ by the second output signal OUTb that is logic ‘low’.

In the example shown in FIG. 2, compensating unit 150 lengthens the logic ‘high’ range of the second input clock signal INb and shortens the logic ‘high’ range of the first input clock signal according to the detected-signal DET_OUT. Finally, the duty ratio of the first and second input clock signals IN and INb is set as 50 to 50. The above explanation describes ideal operation of a conventional DCC. Hereinafter, problematic operation of the conventional technology will be described.

FIG. 3 is a detailed circuit diagram of the latching unit 130 in FIG. 1. New reference numerals are given to the input unit and output unit for the sake of convenience in description.

Referring to FIG. 3, the latching unit 130 is generally formed to include a first NAND gate NAND1 and a second NAND gate NAND2. The first and second NAND gates NAND1 and NAND2 can use values output from each other as input values. The first and second NAND gates NAND1 and NAND2 may include a first PMOS transistor PM1 and a second PMOS transistor PM2 and a fourth and fifth PMOS transistors PM4 and PM5. The latching unit 130 stores a different voltage values at a node C and a node D.

The operating regions of the first and fourth PMOS transistors PM1 and PM4 are changed in response to the voltage levels of the node C and the node D. The operating region is one of a saturation region, a cut-off region, and a linear region. Thus a loading capacitance of the node A is changed in response to the operating regions of the first PMOS transistor PM1 and the fourth NMOS transistor NM4.

Similarly, a loading capacitance of the node B in the second NAND gate NAND2 is changed according to the voltage level of the node C and the node D. In other words, the voltage level of the node C and the node D are maintained different from each other. Thus, loading capacitance in the node A is different from loading capacitance of the node B each other.

To be more accurate, Equation 2 has to further include additional loading capacitance C_{LAT1} that is a loading capacitance in the node A. Also, Equation 1 has to further include additional loading capacitance C_{LAT2} that is a capacitance value in the node B.

FIG. 4 is a timing diagram describing voltage level considering additional capacitors of the latching unit 130.

Like FIG. 2, FIG. 4 shows a situation in which the logic ‘high’ range is longer than the logic ‘low’ range of the first input clock signal IN. Conversely, logic ‘high’ range is shorter than the logic ‘low’ range of the second input clock signal INb.

Equation 3, calculates voltage level difference of the second output signal OUTb during the logic ‘high’ range of the first input clock signal IN.

Equation 4, calculates voltage level difference of the first output signal OUT in the logic ‘high’ range of the second input clock signal INb.

$$\begin{matrix}Δ {V}_{OUTb} = \frac{{I}_{on}}{{C}_{1} + {C}_{LAT 2}} {T}_{on} \_IN & [ Eq . 3 ] \\ Δ {V}_{OUT} = \frac{{I}_{on}}{{C}_{2} + {C}_{LAT 1}} {T}_{on} \_INb & [ Eq . 4 ]\end{matrix}$$

Herein, C₁ denotes electrostatic capacity of the first capacitor C1 and C_{LAT2} denotes electrostatic capacity of the latching unit 130 in the node of the second output signal OUTb. C₂ denotes electrostatic capacity of the first capacitor C2. C_{LAT1} is electrostatic capacity of the latching unit 130 in the node of the first output signal OUT outputted. Iₒₙ is a current flowing through the third NMOS transistor NM3 of the enable unit 114.

Herein, it is assumed that electrostatic capacity of C_{LAT2} is larger than electrostatic capacity of C_{LAT1}. Although the logic ‘high’ range T_{ON}_{_{—}}INb of the second input clock signal INb is narrower than the logic ‘high’ range T_{ON}_{_{—}}IN of the first input clock signal IN, the voltage level difference [symbol] V_{OUT} of the first output signal OUT becomes larger than the voltage level difference [symbol] V_{OUTb} of the second output signal OUTb.

As reflected in Equation 3 and Equation 4, slopes of the first and second output signal OUT and OUTb depend on the loading capacitance of C_{LAT1} in the node A and C_{LAT2} in the node B. Since the C_{LAT2} is greater than C_{LAT1}, a voltage level difference over time [symbol] V_{OUT} of the first output signal OUT becomes larger than a voltage level difference over time [symbol] V_{OUTb} of the second output signal OUTb.

Thus, in the above example, the sensing and amplifying unit 112 amplifies the first input clock signal IN to logic ‘low’. The sensing and amplifying unit 112 amplifies the second input clock signal INb to logic ‘high’. The latching unit 130 outputs the detected-signal DET_OUT that is reset to logic ‘low’. The compensating unit 150 lengthens the logic ‘high’ range of the first input clock signal IN and shortens the logic ‘high’ range of the second input clock signal INb based on the detected-signal DET_OUT that is logic ‘low’.

The conventional DCC has a problem. Since of a wrong duty ratio defected, the conventional DCC cannot set duty ratio of the first and second input clock signals IN and INb as 50 to 50. Furthermore, the DCC increases difference of duty ratios.

### SUMMARY OF THE INVENTION

Embodiments of the present invention is directed to providing a semiconductor device circuit for detecting a duty ratio of a signal, which can detect the duty ratio by maintaining equal loading capacitance between output nodes.

Another embodiment of the present invention is directed to providing a duty cycle detector, which can detect a duty ratio using a detecting signal, by maintaining loading equal capacitance between output nodes in a semiconductor device.

In accordance with an aspect of the present invention, there is provided a semiconductor device circuit comprising: a comparing unit which compares a duty ratio of a first and second input clock signals and generates a first output signal and a second output signal; a latching unit which stores the first and second input clock signals and generates a detecting signal in response to the first and second output signals; and an adjusting unit which receives the first and second output signals, and transmits the first and second output signals in response to a voltage level difference of the first and second output signals.

### BRIEF DESCRIPTION OF THE DRAWINGS

FIG. 1 is a circuit diagram for describing a conventional duty cycle correction circuit (DCC).

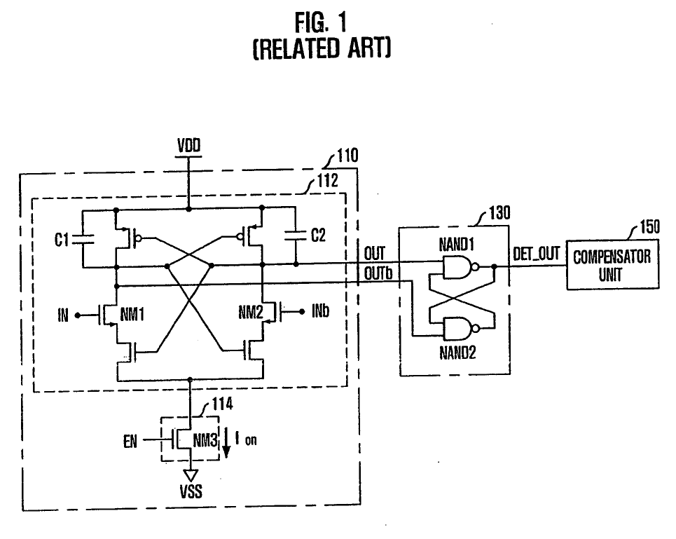

FIG. 2 is a timing diagram describing a voltage level difference of the first and second output signals OUT and OUTb in response to the first and second input clock signals IN and INb in FIG. 1.

FIG. 3 is a detailed circuit diagram of the latching unit 130 in FIG. 1.

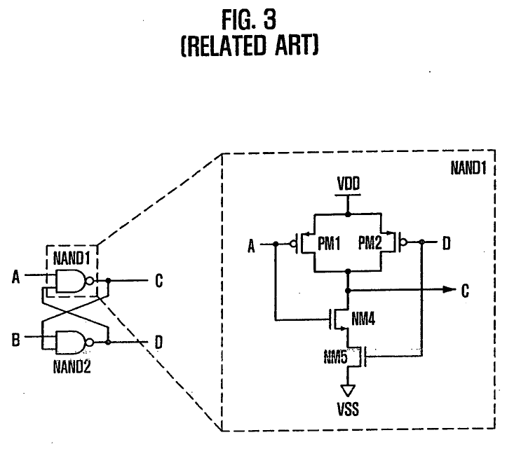

FIG. 4 is a timing diagram describing voltage levels considering additional capacitors of the latching unit 130 in FIG. 1.

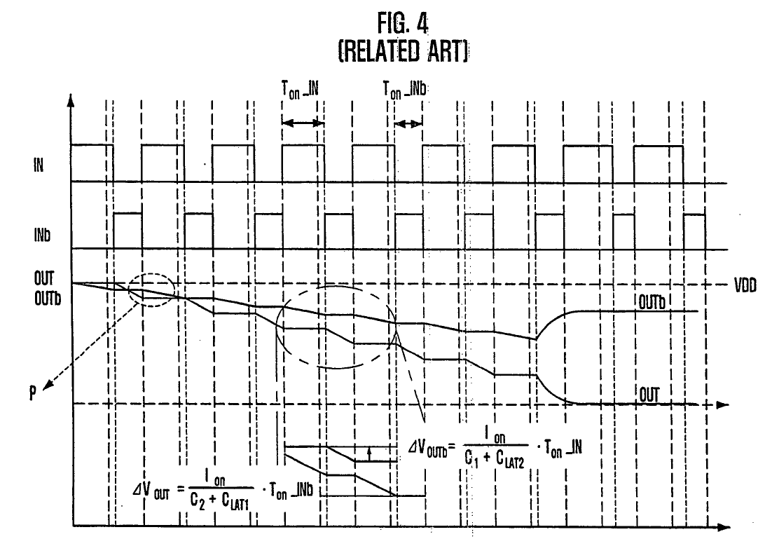

FIG. 5 is a circuit diagram illustrating a duty cycle correction circuit (DCC) in accordance with an embodiment of the present invention.

FIG. 6 is a circuit diagram illustrating an adjusting unit in accordance with another embodiment of the present invention.

### DETAILED DESCRIPTION

Hereinafter, exemplary embodiments of the present invention for detecting a duty ratio of signals in a semiconductor device circuit in accordance with are described in detail with reference to the accompanying drawings.

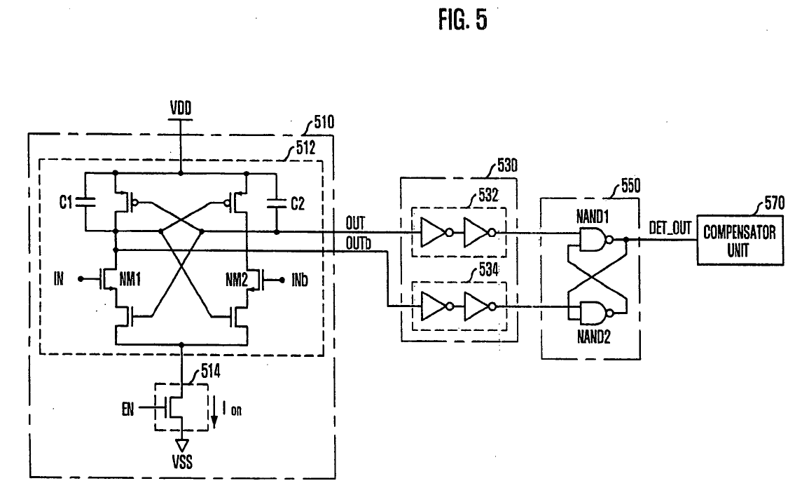

FIG. 5 is a circuit diagram for illustrating the duty cycle correction circuit (DCC) in this embodiment. Referring to FIG. 5, the DCC includes a comparing unit 510, an adjusting unit 530, a latching unit and a compensating unit 570. The comparing unit 510 compares duty cycles of first and second input clock signals IN and INb and outputs a first output signal OUT and a second output signal OUTb. The latching unit 550 stores the first output signal OUT and a second output signal OUTb and outputs a detected-signal DET_OUT. The adjusting unit 530 is located between the comparing unit 510 and the latching u763nit 550 and divides or connects the transmission lines in response to a voltage level difference of the first and second output signals OUT and OUTb. The compensating unit 570 compensates the duty ratio of a first and second input clock signals IN and INb.

The comparing unit 510 includes a sensing and amplifying unit 512 for sensing and amplifying the first and second input clock signals IN and INb and an enable unit 514 for operating the sensing and amplifying unit 512 in response to an enable signal EN. The first input clock signal IN has an inverse phase to that of the second input clock signal INb.

The adjusting unit 530 includes a first buffer unit 532 for buffering the first output signal OUT and a second buffer unit 534 for buffering the second output signal OUTb. The first buffer unit 532 and the second buffer unit 534 each include two inverters respectively. Generally, each of the inverters includes a PMOS transistor and an NMOS transistor, and the input capacitance value of the first output signal OUT should be the same as the input capacitance value of the second output signal OUTb.

The latching unit 550 may include a SR-latch having a first NAND gate NAND1 and a second NAND gate NAND2. The latching unit 550 outputs the detected-signal DET_OUT that is set to logic ‘high’ in response to a signal output by the first buffer unit 532 according to the first output signal OUT. The detected-signal DET_OUT is reset to logic ‘low’ in response to a signal output by the second buffer unit 534 according to the second output signal OUTb.

In accordance with this embodiment, as the adjusting unit 530 is located between the comparing unit 510 and the latching unit 550; the adjusting unit 530 can maintain loading capacitances for the transmission lines of the first and second output signals OUT and OUTb equal to each other, which facilitates detecting a precise duty ratio of the first and second input clock signals IN and INb.

The compensating unit 570 controls a pulse width of the first and second input clock signals IN and INb in response to the detected-signal DET_OUT. Namely, when the second output signal OUTb is reset to logic ‘low’, it indicates that the logic ‘high’ range of the first input clock signal IN is longer than the logic ‘high’ range of the second input clock signal INb. The compensating unit 570 shortens the logic ‘high’ range of the first input clock signal IN and lengthens logic ‘high’ range of the second input clock signal INb in response to the detected-signal DET_OUT that is logic ‘low’.

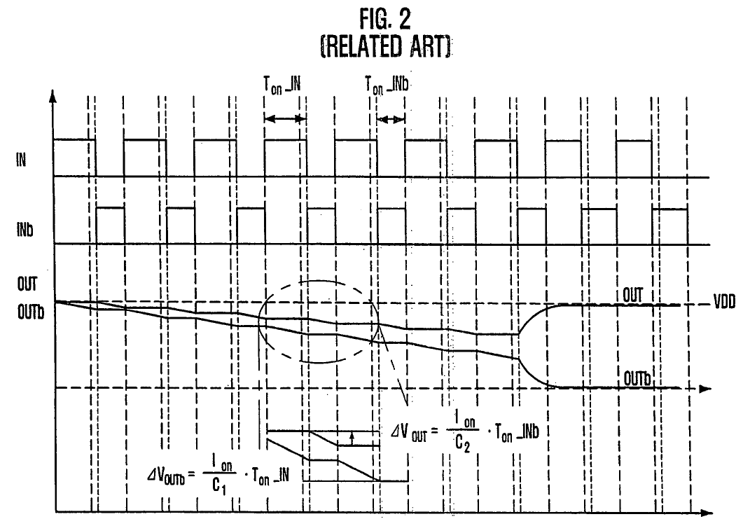

Referring to FIGS. 2 and 5, an operation of the comparing unit 510 will be described briefly hereinafter. First of all, a first NMOS transistor NM1 repeatedly performs turn-on and turn-off operations in response to the first input clock signal IN while an enable signal EN is activated to logic ‘high’. At this time, a first capacitor C1 is discharged by turning on the first NMOS transistor NM1. A second NMOS transistor NM2 repeatedly performs turn-on and turn-off operations in response to the second input clock signal INb. At this time, a second capacitor C2 is discharged by turning on the second NMOS transistor NM2. The discharge amount of the first capacitor C1 depends on the operating region of the first NMOS transistor NM1. A discharge amount of the second capacitor C2 depends on the operating region of the first NMOS transistor NM2. The operating region is one of a saturation region, a cut-off region, and a linear region.

In other words, the first NMOS transistor NM1 is turned on during the logic ‘high’ range of the first input clock signal IN, during which electric charge stored in the first capacitor C1 is discharged. The second NMOS transistor NM2 is turned on during the logic ‘high’ range of the second input clock signal INb, during which electric charge stored in the second capacitor C2 is discharged. Since the logic ‘high’ range of the first input clock signal IN is longer than the logic ‘high’ range of the second input clock signal INb, a turn-on range of the first NMOS transistor NM1 is longer than a turn-on a range of the second NMOS transistor NM2, and the discharge amount of the first capacitor C1 is larger than that of the second capacitor C2.

Discharge of the first capacitor C1 is reflected as a decrease in the voltage level of the second output signal OUTb. Discharge of the second capacitor C2 is reflected as a decrease of voltage level of the first output signal OUT. Thus, in this example, the voltage level of the second output signal OUTb decreases more rapidly than that of the first output signal OUT.

Meanwhile, the input capacitance value of the first buffer unit 532 for the first output signal OUT is the same as the input capacitance value of the second buffer unit 534 for the second output signal OUTb. Thus voltage difference level of the first output signal OUT does not have influence on the input capacitance value of the first and second NAND gates NAND1 and NAND2. On other words, although in the conventional device the first and second output signals OUT and OUTb are under the influence of capacitance value by the latching unit 550, as shown in Equation 3 and Equation 4 described above, the input capacitance values of the first buffer unit 532 and the second buffer unit 534 are the same in this embodiment. Therefore, Equation 1 and Equation 2 can be applied to this embodiment.

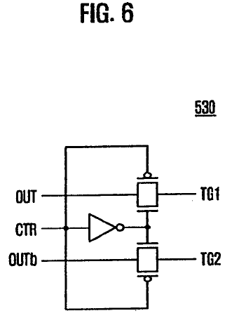

FIG. 6 is a circuit diagram describing another embodiment of adjusting unit 530 in the present invention. Referring to FIG. 6, an adjusting unit 530 includes a first transmission unit TG1 for transmitting the first output signal OUT to the latching unit 550 in response to a control signal CTR and a second transmission unit TG2 for transmitting the second output signal OUTb to the latching unit 550 in response to the control signal CTR. The control signal CTR is inactivated when the comparing unit 510 compares the first input clock signal IN with the second input clock signal INb. The control signal CTR is activated when a voltage level difference of the first and second input clock signals IN and INb is higher than a determined voltage level. As the adjusting unit 530 divides transmission lines which connects the comparing unit 510 with the latching unit 550 when the control signal CTR is inactivated, the adjusting unit 530 makes the input capacitance values of the first and second output signals OUT and OUTb the same.

As the adjusting unit 530 connects the transmission lines which connects the comparing unit 510 with the latching unit 550 when the control signal CTR is activated, the adjusting unit 530 transmits the first and second output signals OUT and OUTb to the latching unit 550. In an alternative embodiment, the control signal CTR can be used instead of the enable signal EN. The control signal CTR is set to the logic ‘high’ while the comparing unit 510 operates in response to the enable signal EN that is set to logic ‘high’. The adjusting unit 530 divides the transmission line. The control signal CTR is reset to the logic ‘low’ while the comparing unit 510 does not operate in response to the enable signal EN that is reset to logic ‘low’. The adjusting unit 530 connects the transmission line.

The adjusting unit 530 maintains equal input capacitance values for the first and second output signals OUT and OUTb. Thus the compensating unit 570 can detect a precise duty ratio of the first and second input clock signal IN and INb. The compensating unit 570 for compensating duty ratio of the first and second input clock signals IN and INb controls pulse widths of the first and second input clock signal IN and INb in response to the detected-signal DET_OUT.

Namely, when the second output signal OUTb is set to logic ‘low’, it means that the first input clock signal IN has a longer logic ‘high’ range than the second input clock signal INb. Therefore, the compensating unit 570 shortens the logic ‘high’ range of the first input clock signal IN and lengthens the logic ‘high’ range of the second input clock signal INb in response to the detected-signal DET_OUT. The loading capacitance of the first output signal OUT is the same as the loading capacitance of the second output signal OUTb, regardless of the voltage level of the latching unit 550. Therefore the semiconductor device circuit can detect duty ratio of signals without considering a loading capacitance of the latching unit 550.

The present invention includes various embodiments which include transistors and logic gates. In the above embodiments, the kind or position of the transistors and logic gates can be changed according to polarity of a signal. Although each of the first and second buffer units 532 and 534 of FIG. 5 described above includes two inverters, the buffer unit 532,534 may include only one inverter. Also, the present invention can be applied to other various embodiments which can maintain loading capacitance in the transmission lines equal to each other.

While the present invention has been described with respect to the specific embodiments, the above embodiments of the present invention are illustrative and not limitative. It will be apparent to those skilled in the art that various changes and modifications may be made without departing from the spirit and scope of the invention as defined in the following claims.

What is claimed is:

1. A circuit for detecting a duty ratio of signals in a semiconductor device, comprising:
a comparing unit which compares a duty cycle of first and second input clock signals input differentially and generates a first output signal and a second output signal;
a latching unit which stores the first and second output signals and generates a detected signal corresponding to the first and second output signals; and
an adjusting unit which receives the first and the second output signals, and transmits the first and the second output signals to the latching unit based on a voltage level difference of the first and second output signals.

2. The circuit of claim 1, wherein the comparing unit includes:
a sensing and amplifying unit which senses and amplifies the first and second input clock signals and generates the first and second output signals; and
an enable unit which enables the sensing and amplifying unit in response to an enable signal.

3. The circuit of claim 1, wherein the adjusting unit maintains input loading capacitances for the first output signal and the second output signal which are equal to each other.

4. The circuit of claim 1, wherein the adjusting unit includes:
a first buffer which receives and buffers the first output signal; and
a second buffer which receives and buffers the second output signal.

5. The circuit of claim 1, wherein the adjusting unit includes:
a first transmission unit which transmits the first output signal to the latching unit in response to a control signal enabled when a difference between voltage levels of the first output signal and the second output signal is greater than a predetermined amount; and
a second transmission unit which transmits the second output signal to the latching unit in response to the control signal.

6. The circuit of claim 5, wherein the control signal is responsive to the enable signal.

7. The circuit of claim 1, wherein the latching unit outputs the detected signal in response to a signal output by the adjusting unit based on the first output signal and the second output signal.

8. The circuit of claim 1, wherein the latching unit includes an SR-latch performing set/reset operations in response to the output signals provided by the adjusting unit.

9. The circuit of claim 1, further comprising:
a compensating unit which adjusts the duty ratio of the first and second input clock signals in response to the detected signal.
